(19) United States
(12) Patent Application Publication
(10) Pub. No.: US 2006/0214119 A1
(43) Pub. Date: Sep. 28, 2006

(54) Pattern data creation method, pattern data creation program, computer-readable medium and fabrication process of a semiconductor device

(75) Inventors: Syuzi Katase, Kawasaki (JP); Kazuhiko Takahashi, Kawasaki (JP); Masahiko Minemura, Kawasaki (JP); Shuji Osada, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/180,792

(22) Filed: Jul. 14, 2005

(30) Foreign Application Priority Data
Mar. 28, 2005 (JP) 2005-093002

(51) Int. Cl. G21K 5/10; H01J 37/08

(52) U.S. Cl. 250/492.22

(57) ABSTRACT

A pattern data creation method creates mask pattern data on an exposure mask, the exposure mask having a surface divided into plural unit regions and the mask pattern data including pattern data parts each defined for one of the plural unit regions, each of the pattern data parts including pattern information of a pattern included in the unit region and header information indicative of a location of the unit region on the surface of the exposure mask. The pattern data creation method includes the steps of replacing, in a part of said plural unit regions, the pattern information in the mask pattern data part with new pattern information, and reconstructing the header for that unit region in which the pattern information is replaced.

### CROSS-REFERENCE TO RELATED APPLICATION

The present application is based on Japanese priority application No. 2005-093002 filed on Mar. 28, 2005, the entire contents of which are hereby incorporated by reference.

### BACKGROUND OF THE INVENTION

The present invention generally relates to fabrication of semiconductor devices and more particularly to fabrication of exposure mask used in the fabrication process of a semiconductor device.

Photolithography process is a fundamental and important process in fabrication of semiconductor devices.

A photolithography process is generally conducted by an exposure mask, wherein such an exposure mask is formed by patterning an opaque film such as a Cr film on a transparent substrate of typically a quartz glass based on design data of the semiconductor device while using an exposure process such as an electron beam exposure process.

In such formation of the exposure mask, the design data created by the designer is converted to pattern data corresponding to the mask pattern actually formed on the mask, and the exposure of the exposure mask is conducted according to such pattern data.

### REFERENCES

Patent Reference 1 Japanese Laid-Open Patent Application 10-334134

### SUMMARY OF THE INVENTION

FIG. 1 shows an overview of the fabrication process of a semiconductor device that includes the process of converting design data to pattern data for fabrication of an exposure mask. Further, FIG. 2 shows an overview of the conversion process converting the design data to pattern data, while FIGS. 3A and 3B show an example of the pattern data thus converted.

Referring to FIG. 1, a designer of the semiconductor device creates design data in the step 1, and the design data thus created is converted to pattern data in the step 2, and with this, pattern data corresponding to the design data is obtained in the step 3.

Further, in the step 4, an exposure mask called reticle is fabricated based on the pattern data thus obtained in the step 3, and a semiconductor pattern is exposed to a semiconductor substrate in the step 5 according to the design data while using the reticle thus fabricated.

FIG. 2A schematically represents the design data of a semiconductor device created in the step 1 by the designer, wherein it should be noted that the design data is generally represented in terms of cells. Because the data format of cells is not suitable for representing physical patterns of exposure mask, the conversion processing of the step 2 explained before is conducted so as to convert the cell data of FIG. 2A to pattern data shown in FIG. 2B. Here, it should be noted that FIG. 2B represents the surface of the exposure mask and the surface of the exposure mask is divided into plural segments and plural stripes.

Hereinafter, the description will be made for the case of using so-called MEBES data format (registered trademark of ETEC Corporation) for the pattern data, while it should be noted that the present invention is by no means limited to MEBES data but is applicable to any pattern data format as long as it divides the surface of the exposure mask into plural regions and defines a pattern in each of the regions. For example, the present invention is applicable also to so-called JEOL format provided by JEOL Ltd.

FIGS. 3A and 3B show an example of the pattern data of FIG. 2B.

Referring to FIG. 3A, one segment of FIG. 2B is represented by data units each having a size of 2048 bytes wherein it should be noted that one segment includes header information representing the location and size of the segment and pattern information representing the actual pattern provided by the segment.

In the example of FIG. 3B, it is described that the segment 1 starts from 2048th byte and extends to 8192-th byte and that the stripe 1 defined therein is a rectangular pattern (Rec) having an initial x coordinate of 11 and a final x coordinate of 22, an initial y coordinate of 11 and a final y coordinate of 22.

Meanwhile, with recent ultrafine semiconductor devices, the number of patterns formed on an exposure mask is enormous, and the conversion process in the step 2 of FIG. 1 imposes a problem of heavy load for the computer used for this purpose.

Thus, any correction of the design data under such a situation invites intolerable waste of computer resources, as such a correction necessitates stepping back to the step 2 and subsequent re-execution of the conversion process from the design data to the pattern data each time such a correction comes up.

Thus, in a first aspect, the present invention provides a pattern data creation method for creating mask pattern data on an exposure mask, said exposure mask having a surface divided into plural unit regions, said mask pattern data comprising pattern data parts each defined for one of said plural unit regions, each of said pattern data parts comprising pattern information of a pattern included in said unit region and header information indicative of a location of said unit region on said surface of said exposure mask, said pattern data creation method comprising the steps of:

replacing, in a part of said plural unit regions, said pattern information in said mask pattern data part with new pattern information; and

reconstructing said header for said unit region in which said pattern information is replaced.

Further, the present invention also includes a fabrication method of a semiconductor device that uses a mask fabricated according to such a pattern data creation method. Further, the present invention includes a program for executing such a pattern data creation method and a recording medium on which such a program is recorded. Further, the present invention includes a computer used for executing such a program.

According to the present invention, the computer time needed for converting the design data to pattern data corresponding to the mask pattern on the exposure mask for the case in which there came up the needs of correcting the design data after the data conversion to the pattern data has been made already, is reduced significantly, by merely converting a specific part of the design data corresponding to the cell where the correction has been made in the design data, to form a corrected partial mask pattern data, and simply replacing the part of the mask pattern data corresponding to the foregoing corrected cell with the corrected partial mask pattern data. Thereby, the computer time needed for data conversion is reduced drastically and it becomes possible to carry out the correction of the mask pattern with low cost.

Other objects and further features of the present invention will become apparent from the following detailed description when read in conjunction with the attached drawings.

### BRIEF DESCRIPTION OF THE DRAWINGS

FIG. 1 is a diagram showing a fabrication process of a semiconductor device including the process of fabricating an exposure mask according to a related art;

FIGS. 2A and 2B are diagrams showing the correspondence between design data and pattern data on an exposure mask;

FIGS. 3A and 3B are diagrams showing an example of the pattern data;

FIG. 4 is a diagram showing the pattern data creation method according to a first embodiment of the present invention;

FIGS. 5A and 5B are diagrams showing a part of FIG. 4;

FIGS. 6A and 6B are diagrams explaining the conversion of design data to pattern data in the process of FIG. 4;

FIGS. 7A-7C are diagrams explaining an example of replacing the pattern data in the process of FIG. 4;

FIGS. 8A and 8B are further diagrams explaining the example of replacing the pattern data in the process of FIG. 4;

FIGS. 9A-9C are further diagrams showing an example of replacing the pattern data in the process of FIG. 4;

FIG. 10 is a diagram showing the overall process of pattern data creation corresponding to FIG. 4;

FIG. 11 is a diagram showing a pattern data creation method according to a second embodiment of the present invention;

FIGS. 12A-12C are diagrams showing an example of replacing the pattern data in the embodiment of FIG. 11;

FIG. 13 is a diagram showing the process pattern data creation according to a third embodiment of the present invention;

FIGS. 14A-14C are diagrams showing an example of replacing the pattern data in the embodiment of FIG. 13;

FIGS. 15A-15G are diagrams showing a fabrication process of an exposure mask according to a fourth embodiment of the present invention;

FIG. 16 is a diagram showing the construction of an exposure mask fabrication system according to a fifth embodiment of the present invention;

FIG. 17 is a diagram showing the construction of a workstation used in FIG. 16.

### DETAILED DESCRIPTION OF THE INVENTION

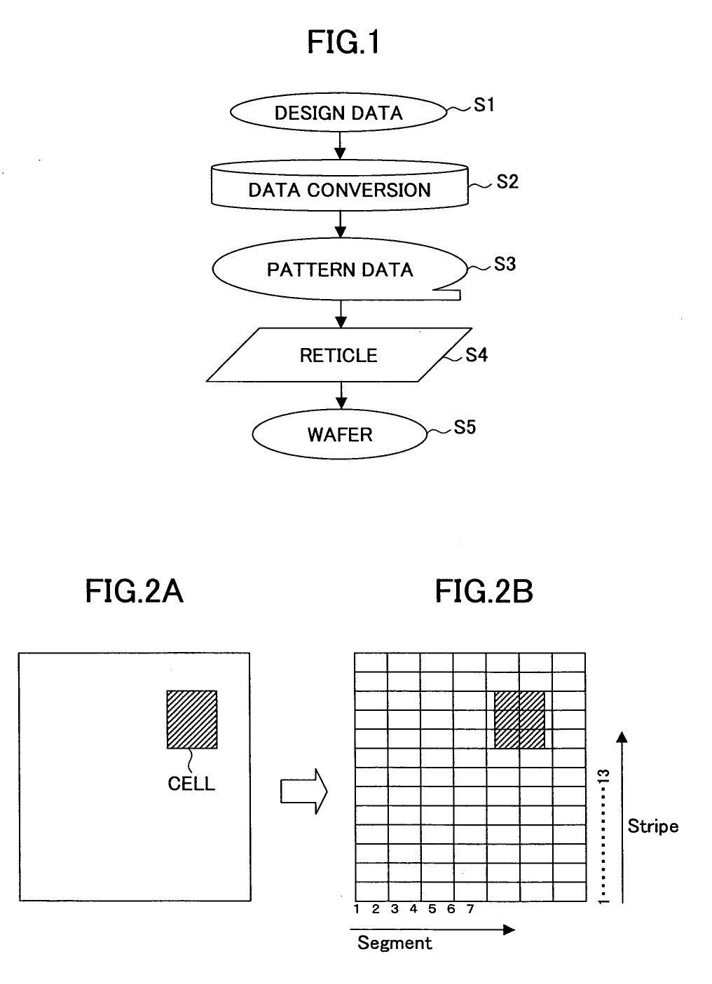

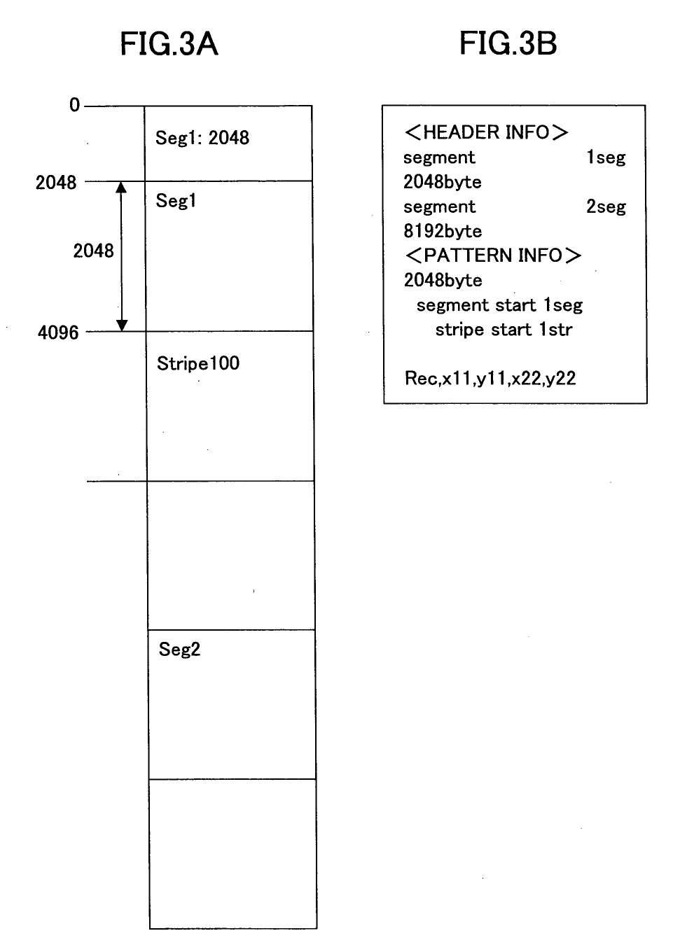

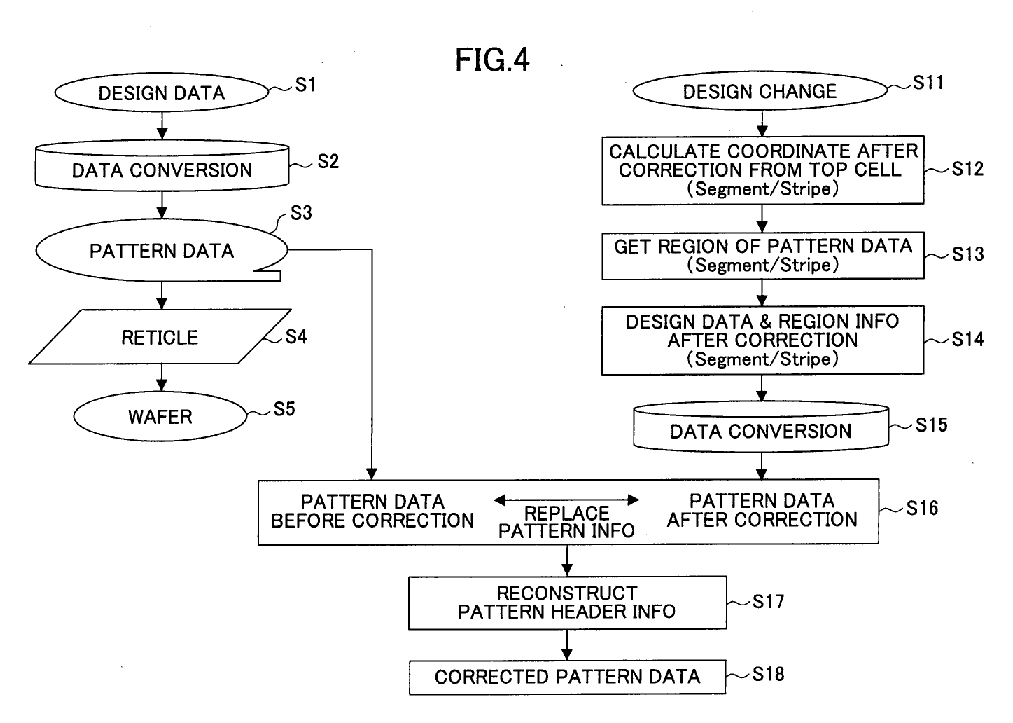

FIG. 4 is a diagram showing an overview of the pattern data creation method according to a first embodiment of the present invention, wherein those parts of FIG. 4 explained previously with reference to FIG. 1 are designated by the same reference numerals and the description thereof will be omitted.

Referring to FIG. 4, in the case there comes up a need of changing the design in the step 11, the coordinate of the cell in which the correction is to be made is calculated first in the step 12 with regard to the overall design data called “top cell”, and the coordinates of the segments and stripes identifying the region of the pattern data on the exposure mask corresponding to the foregoing specific cell are acquired in the step 13.

Further, in the step 14, the design data after correction is acquired together with region information, which specifies the region in which the foregoing correction is to be made, in the form of the coordinates of the segments and stripes. Further, in the step 15, only the design data of the foregoing correction region is subjected to the conversion process for converting the design data to the pattern data. Here, it should be noted that identification of the cell subjected to the correction may be made by comparing the overall design data before and after the correction. Alternatively, the identification may be made manually by the designer at the time of the correction.

Further, in the step 16, the pattern information of the region acquired in the step 13, which region being included in the original overall pattern data obtained previously in the step 3, is replaced with the pattern information of the corrected pattern data acquired in the step 14.

Thereby, it should be noted that the pattern data size is not always identical before and after the correction. Further, there may be insertion or deletion of the pattern with such a correction. Thus, it is not sufficient to merely replace the pattern before the correction with the corrected pattern, and the present invention carries out reorganization of the pattern header information specifying the coordinate of the related segments and coordinates of the pattern in the step 17, in addition to the replacement of the pattern information in the step 16.

Upon completion of the step 17, corrected pattern data is obtained in the step 18, and fabrication of the exposure mask is conducted by using such corrected pattern data.

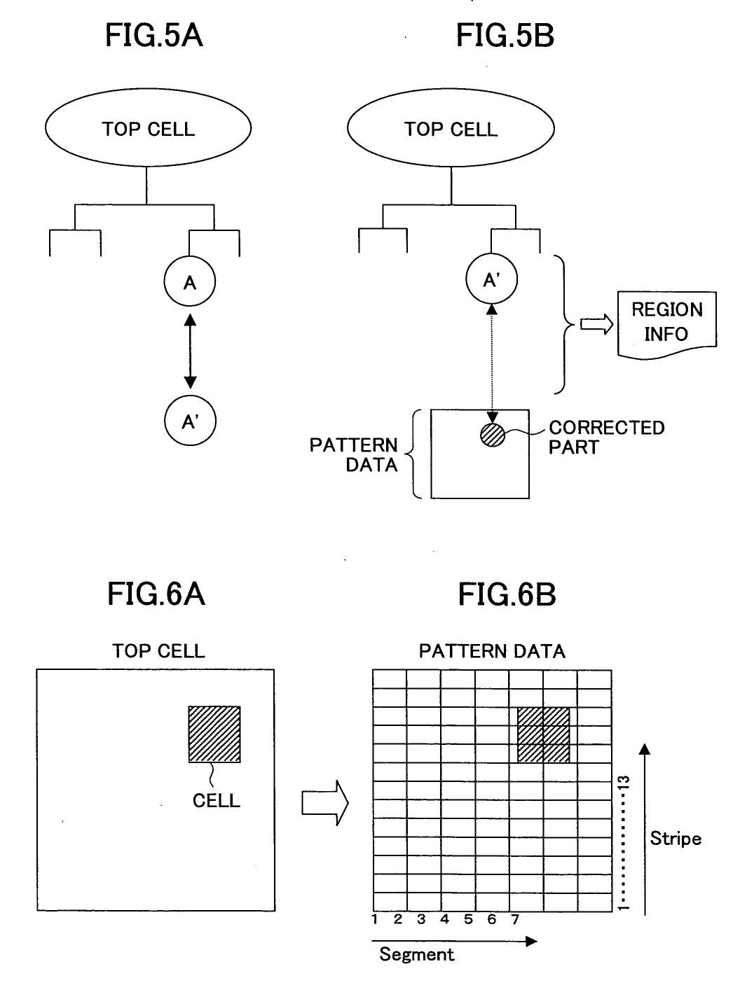

FIG. 5A corresponds to the steps 11 and 12 of FIG. 4 and shows the situation in which design data A is replaced with different design data A′ in a specific cell included in the overall design data (“top cell”). On the other hand, FIG. 5B corresponds to the step 14 of FIG. 4 and shows the situation in which the region information of the cell after correction to the design data A′ is acquired.

FIG. 6A shows an example of changing the design data of a cell included in the top cell, while FIG. 6B shows the segments and stripes on the exposure mask that are influenced with the design data change of FIG. 6A.

As can be seen in FIG. 6B, the cell that has experienced the design change in FIG. 6A do not always correspond to a single unit region specified by a segment or stripe on the exposure mask, but there can appear a situation in which plural unit regions each specified by a segment coordinate and a stripe coordinate correspond to the cell of FIG. 6A.

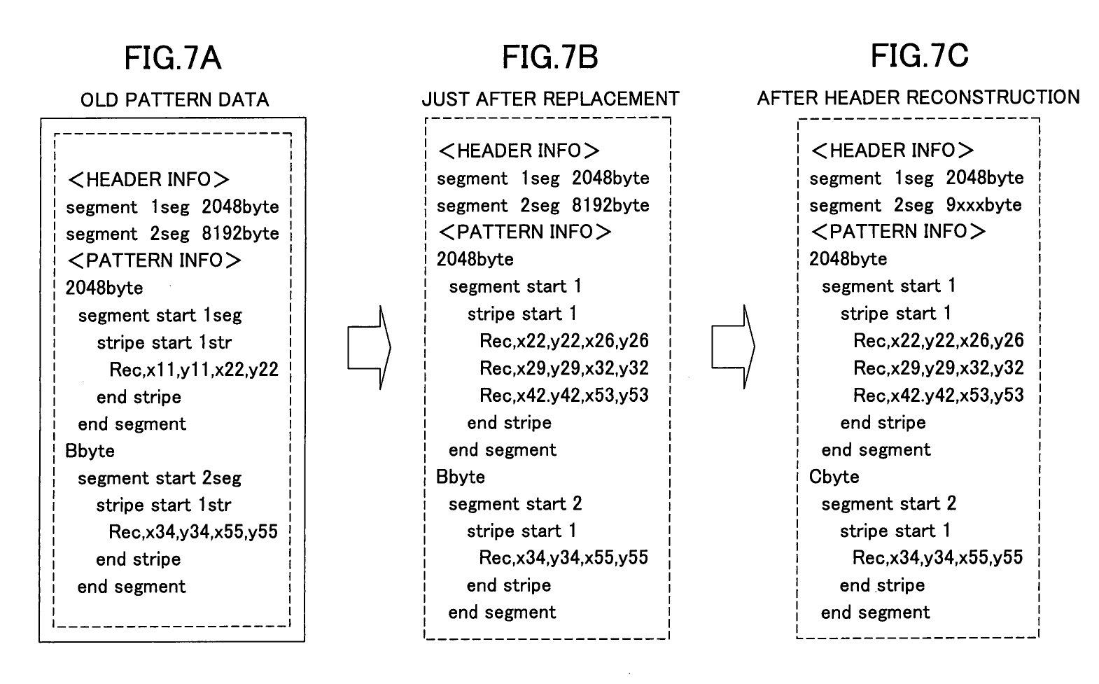

FIGS. 7A-7C show an example of replacement of the pattern information and reorganization of the header information in the step 17 of FIG. 4, wherein it should be noted that FIG. 7A shows the region acquired in the step 13 of FIG. 4 as the region in which the pattern data correction is to be made. On the other hand, FIG. 7B corresponds to the step 16 of FIG. 4 and represents the situation in which the pattern information of the pattern data acquired in the step 14 of FIG. 4 has been used to replace the pattern information of FIG. 7A. In the state of FIG. 7B, no reorganization of the header information has been made yet.

Further, in the state of FIG. 7C, the header information is reorganized in correspondence to the step 17 of FIG. 4.

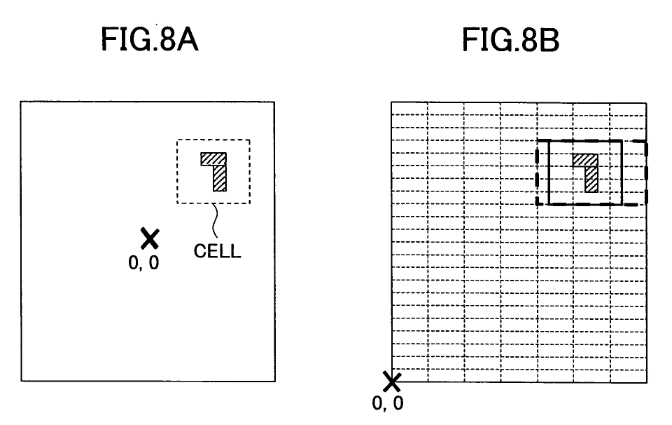

FIG. 8A corresponds to the step 11 of FIG. 4 or FIG. 5B and shows the state in which the design data is corrected for the part in the cell, while FIG. 8B shows the pattern data on the exposure mask corresponding to the change of design data of FIG. 8A.

As can be seen in FIG. 8A, the origin (0,0) of the coordinate is set at the center of the exposure mask in the representation of the top cell, while the pattern data describing the pattern formed on the exposure mask uses a coordinate system that defines the origin at the left bottom corner of the mask region. Thus, it should be noted that the pattern information shown in FIGS. 7A-7C are described by the coordinate system of FIG. 8B that defines the origin (0,0) as illustrated therein.

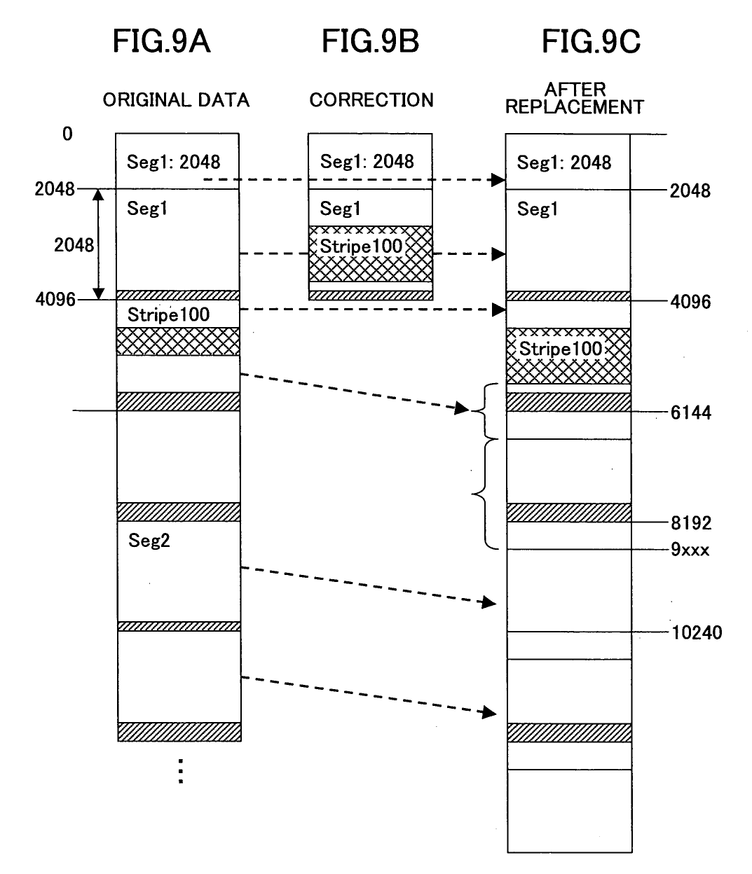

FIGS. 9A-9C represents an example in which insertion of an additional pattern has been made at the time of modification of the design data. Here, it should be noted that FIG. 9A represents the original pattern data acquired by the step 3 of FIG. 4, while FIG. 9B represents the additional pattern data created in the step 11 of FIG. 4 for the purpose of correction and converted in the step 15. Further, FIG. 9C shows the situation in which the additional pattern data of FIG. 9B is inserted into the pattern data of FIG. 9A and the header information is reorganized further.

Referring to FIG. 9C, the additional pattern data of FIG. 9B is inserted to the location of the stripe 100, and as a result, the data after the foregoing stripe 100 are moved down as represented in FIG. 9C by an arrow while maintaining the original contents thereof. It should be noted that such shifting of the data is represented by the reorganization of the header information represented in FIG. 7C.

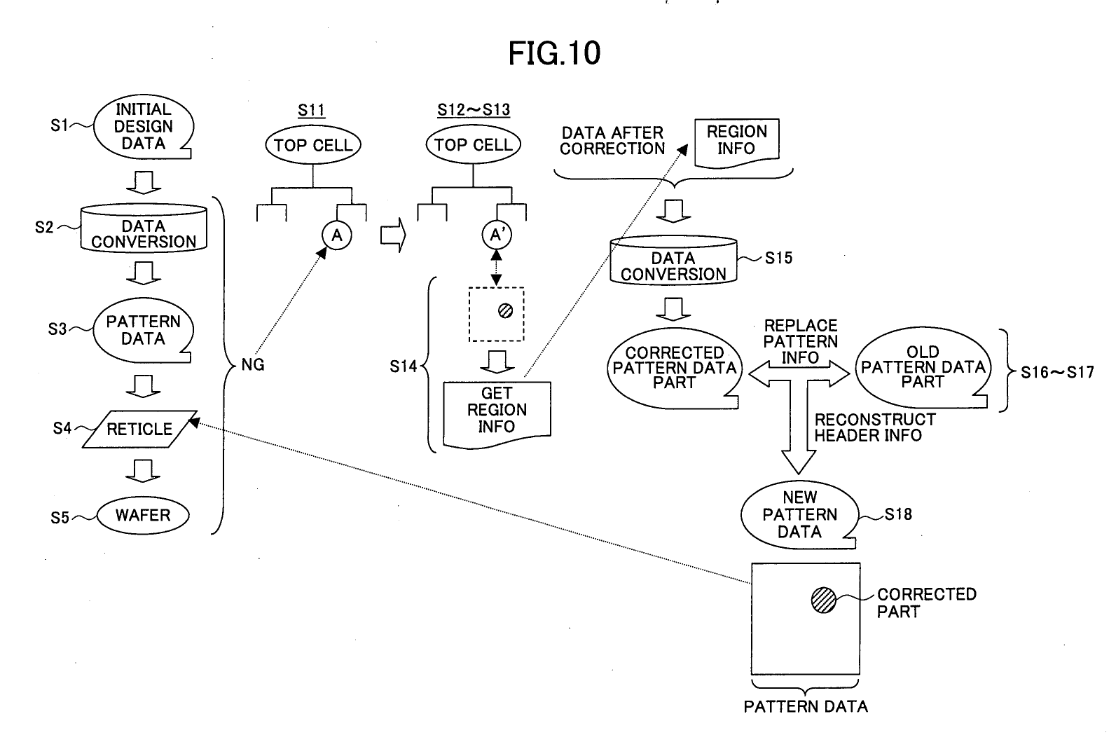

FIG. 10 is a diagram summarizing the foregoing first embodiment explained heretofore.

Referring to FIG. 10, in the case the pattern data 3 acquired in the step 3 needs correction, a cell A to be changed is identified in the design data in the step 11 and the cell A is changed to a cell A′ in the steps 12-13. Further, in the step 14, the segment and stripe coordinates corresponding to the cell A′ of FIG. 10 are acquired as the region information, and the design data for the cell A′ is converted to the pattern data in the step 15 to form a pattern data part.

Further, the pattern data part thus converted is used to replace the pertinent part of the original pattern data in the steps 16-17, and the corrected pattern data is acquired in the step 18 after reorganization of the header information.

Further, the process proceeds from the step 18 to the step 4 and fabrication of the reticle is conducted. Further, by exposing a pattern on a semiconductor wafer while using the reticle thus obtained, a desired semiconductor device is fabricated.

Thus, with the present embodiment, only the pattern data part corresponding to a specific cell of the top cell subjected to the design change is selectively used to replace the original pattern data.

### Second Embodiment

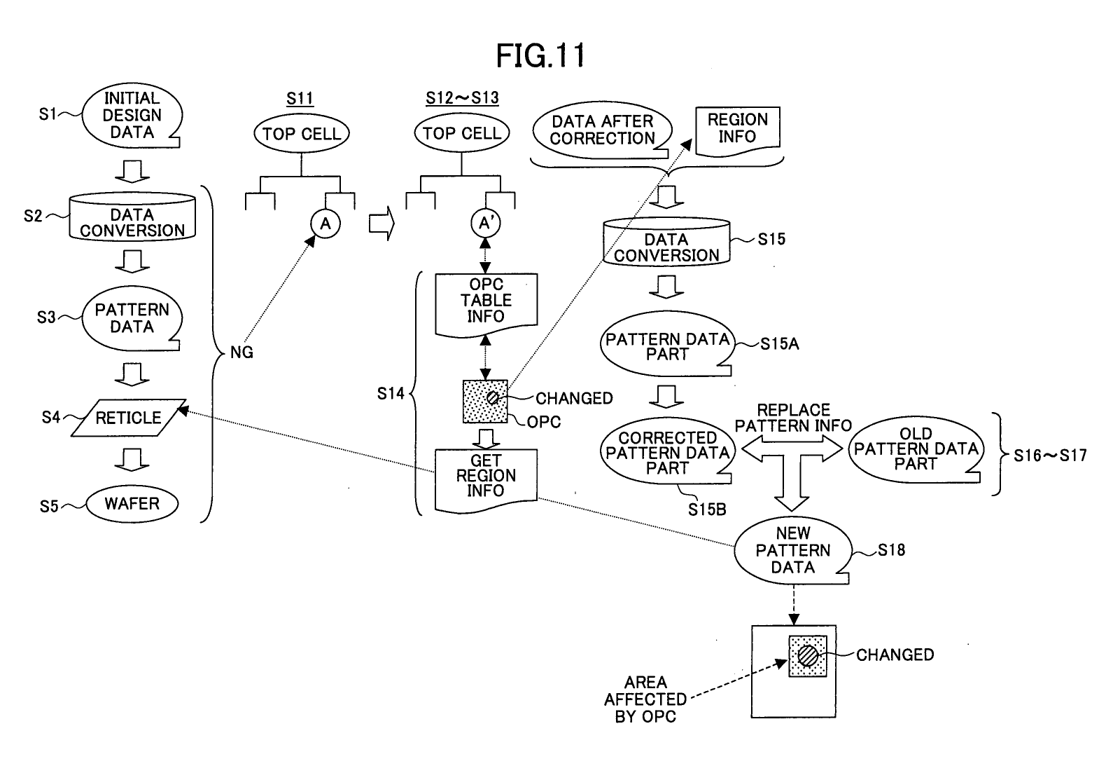

FIG. 11 shows the pattern data formation method according to a second embodiment of the present invention.

Referring to FIG. 11, the present embodiment is generally identical with the embodiment of FIG. 10 explained before, except that the present embodiment includes optical proximity effect correction.

It should be noted that, in the case of exposing extremely fine patterns on a wafer in the step 5 with high density, there is a possibility that the patterns on the wafer cause interference as a result of optical proximity effect and the exposure pattern experiences distortion.

In view of the foregoing, it is generally practiced in the art to carry out OPC (optical proximity correction) processing for the patterns on the reticle for proximity correction, particularly in the reticles designed for exposure of high-density patterns. For this purpose, OPC patterns are formed on the reticle.

In the preceding embodiment, in which the pattern data part corresponding to the corrected design data part is used simply to replace the pattern data on the exposure mask, there is a possibility that conformity of the OPC pattern with the surrounding patterns may be lost with such a replacement of the pattern part, particularly in the case in which the reticle is designed to carry patterns with high pattern density. In such a case, there is a possibility that effective proximity correction is no longer attained.

Thus, with the present embodiment, the step 14 is modified to include the process of referring to an OPC table upon modification of the design data of a particular cell in the step 11 so as to acquire the region information of the OPC cell that contributes to the proximity effect correction in the surrounding region surrounding the cell in which the data correction has been made, in addition to the region information for the foregoing cell in which the design correction has been made.

Further, in the step 15, these cells are subjected to data conversion separately, and the pattern data for the OPC cell is acquired in the step 15A, and the pattern data corresponding to the design data subjected to correction is acquired in the step 15B.

Thus, with the present invention, correction of the pattern data corresponding to the design change and associated correction of the OPC pattern data are achieved simultaneously in the step 18, by replacing the old OPC pattern data part and the old pattern data part with the new pattern data part and new OPC pattern data part in the steps 16-17.

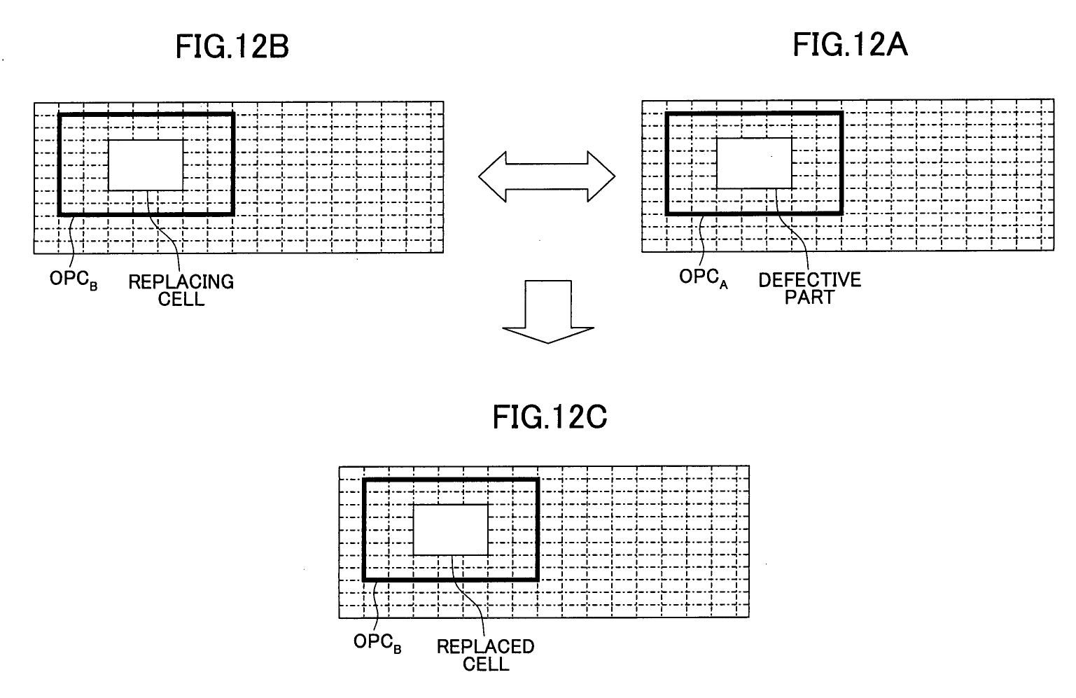

FIGS. 12A-12C show the summary of the pattern data change including the OPC pattern according to the present embodiment.

Referring to FIGS. 12A-12C, FIG. 12A shows the pattern data corresponding to the step 3 and including therein defects, while it should be noted that there is formed an OPC pattern region OPC_{A} around the defective pattern with adaptation to such a defective pattern. On the other hand, FIG. 12B shows a pattern corresponding to the corrected design data, wherein it will be noted that there is formed an OPC pattern OPC_{B} around the corrected pattern with adaptation to the pattern thus corrected.

Now, in order to avoid the enormous computer time for converting the entire corrected design data to produce the entire pattern data of FIG. 12B, the present invention uses the pattern data of FIG. 12A obtained already and applies the conversion only to the OPC pattern OPC_{B} and to the pattern data part represented in FIG. 12B. With this, it becomes possible to obtain the pattern shown in FIG. 12C in short time.

For example, it becomes possible with the present embodiment to reduce the computer time needed to obtain the pattern data of FIG. 12C to 10 hours for the case of a logic device of 90 nm node, in contrast with the case of directly obtaining the pattern data of FIG. 12B from the design data, which requires the computer time of 96 hours.

### Third Embodiment

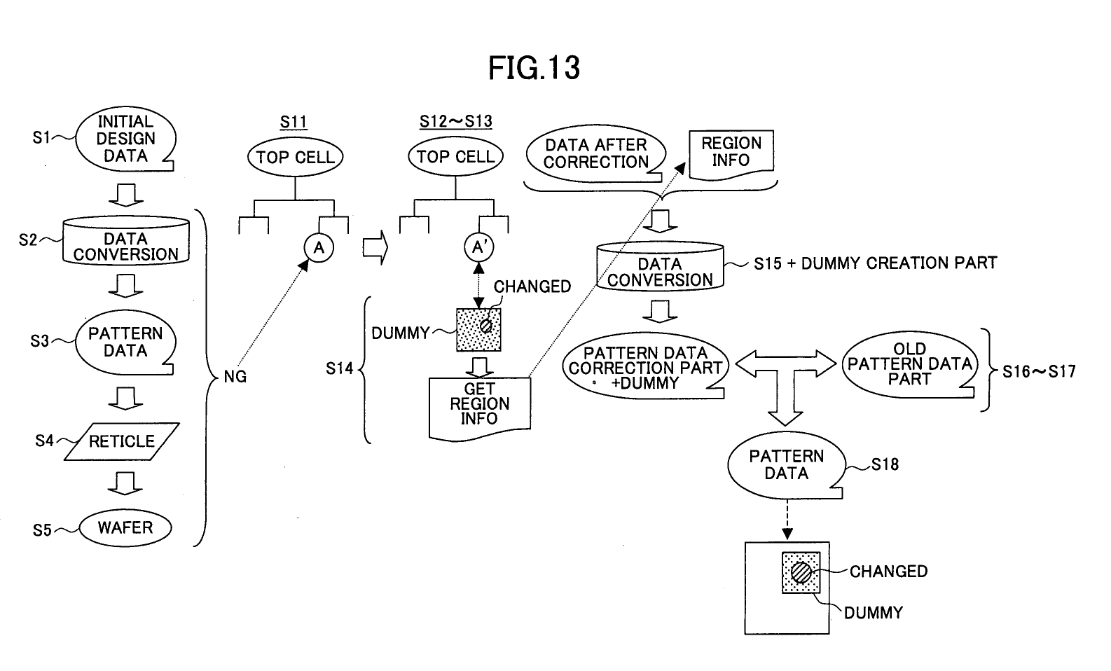

FIG. 13 shows the pattern data creation method according to a third embodiment of the present invention.

Referring to FIG. 13, the present embodiment is similar to that of FIG. 10 explained before, except that the present embodiment includes a dummy pattern creation step.

In semiconductor technologies, it is generally practiced to insert dummy patterns in the region of the substrate where the pattern density is low, for ensuring uniformity of processing such as CMP (chemical mechanical polishing).

While the embodiment of FIG. 10 has simply used the pattern data part corresponding to the part of the design data where the correction has been made for replacing the pattern data on the exposure mask, it is possible that there comes up a situation in which the density of the patterns on the semiconductor wafer is different before and after the replacement as a result of the design change. In such occasion, conformity between the pattern and the surrounding dummy pattern may be lost particularly in the vicinity of the part where the replacement has been made. Thereby, there is a possibility that desired uniform CMP processing becomes no longer possible.

Thus, with the present embodiment, the step 14 is conducted, in the case the design data of a specific cell is changed in the step 11, so as to collect the region information of the dummy cells surrounding the foregoing specific cell.

Further, in the step 15, the design data of the foregoing changed part and the dummy cell region are converted to form a corresponding pattern data, wherein the step 15 is conducted further to form the dummy pattern data corresponding to the pattern data thus formed.

Further, in the steps 16-17, the dummy pattern data and the pattern data thus created are used to replace the old pattern data, and thus, modification of the pattern data corresponding to the design change and modification of the dummy pattern data corresponding to the modification of the pattern data are achieved simultaneously in the step 18.

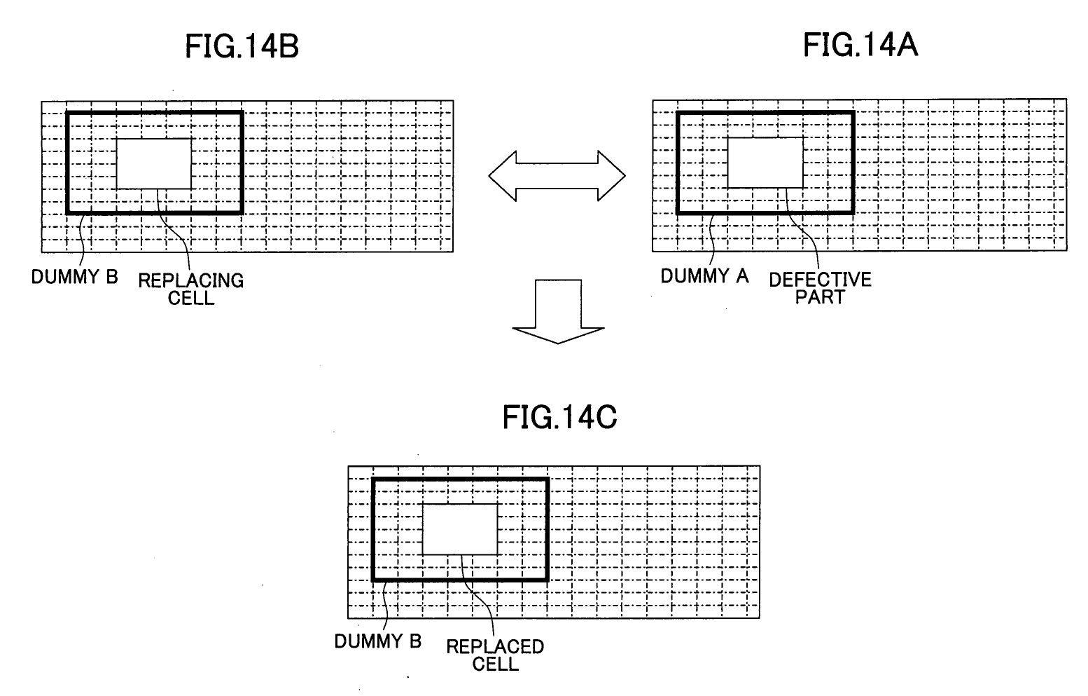

FIGS. 14A-14C provide the overview of such a change of the pattern data according to the present embodiment that includes the corresponding change of the dummy pattern data.

Referring to FIGS. 14A-14C, FIG. 14A shows the pattern data corresponding to the step 3 in which defects are included, wherein it should be noted that there is formed a dummy pattern region Dummy_{A} so as to surround the foregoing defective pattern wherein the dummy pattern region Dummy_{A} includes therein dummy patterns adapted to the foregoing defective pattern.

In contrast, FIG. 14B shows the pattern data corresponding to the corrected design data wherein it will be noted that there are formed dummy patterns adapted to the foregoing corrected pattern data in the dummy pattern region Dummy_{B} surrounding the corrected dummy pattern.

Here, it should be noted that the present invention can successfully reduce the enormous time, which is needed for converting the overall design data to derive the entire pattern data of FIG. 14B, by utilizing the pattern data of FIG. 14A already obtained and by merely replacing the dummy pattern Dummy_{A} and the defective pattern data of FIG. 14A with the dummy pattern Dummy_{B} and the corrected pattern data of FIG. 14B, as shown in FIG. 14C.

### Fourth Embodiment

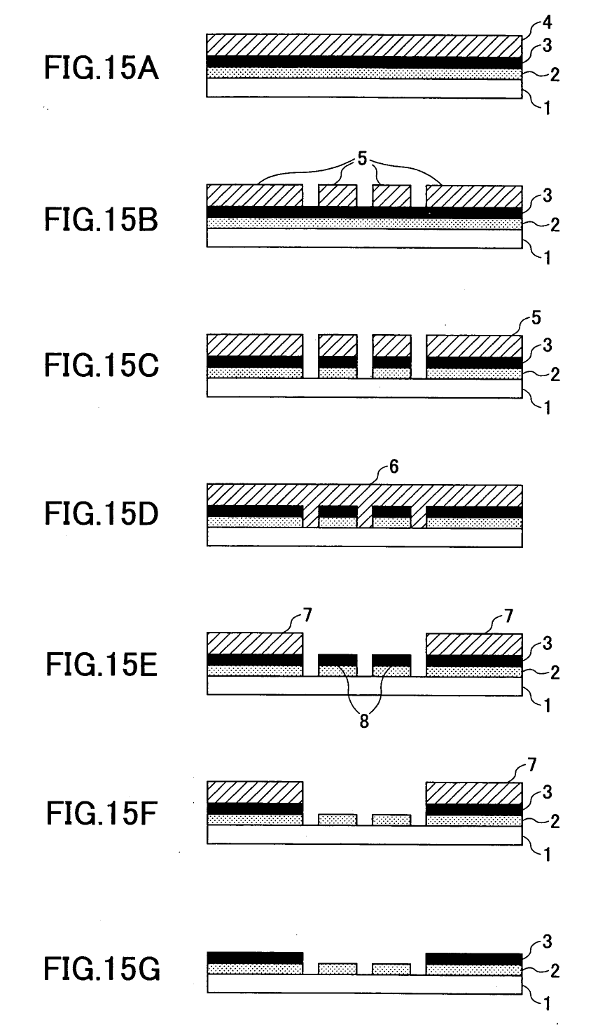

FIGS. 15A-15G show the fabrication process of an exposure mask according to a fourth embodiment of the present invention.

Referring to FIG. 15A, the exposure mask is the one used for exposure of a 90 nm-node logic device and has a structure in which a MoSiON film 2 is formed on a quartz glass substrate 1 as a half-tone phase shift mask, and an opaque film 3 is formed on the phase shift film 2 in the form of lamination of a Cr film and a chromium oxide film. Further, in the state of FIG. 15A, a resist film 4 is formed on the opaque film 3.

Next, in the step of FIG. 15B, exposure and development is conducted to the resist film 4 by using the exposure mask explained in any of the embodiments of the present invention before, and there is formed a resist pattern 5 as a result of patterning of the resist film 4.

Further, in the step of FIG. 15C, the opaque film 3 is patterned while using the resist pattern 5 as a mask, and there is formed an opaque pattern as a result.

Next, in the step of FIG. 15D, the resist pattern 5 is removed and a new resist film 6 is formed.

Further, in the step of FIG. 15E, the entire main region is exposed and a second resist pattern 7 is formed with subsequent development. Further in the step of FIG. 15F, the opaque pattern 8 exposed in the main region is removed while using the resist pattern 7 thus formed as a mask.

Further, in the step of FIG. 15G, the resist pattern 7 is removed and the exposure mask is completed.

As explained previously, with such fabrication process of exposure mask of the present invention, a computer time of 96 hours, which computer time has been needed conventionally in a logic device of 90 nm node for reflecting any design change coming up in the design data of the semiconductor device to the pattern data formed on the exposure mask, is successfully reduced to 10 hours.

Including the mask fabrication process, it becomes possible with the pattern data creation method of the present invention to reduce the processing work for reflecting the design change to the exposure mask from conventional 11 days to 7 days.

### Fifth Embodiment

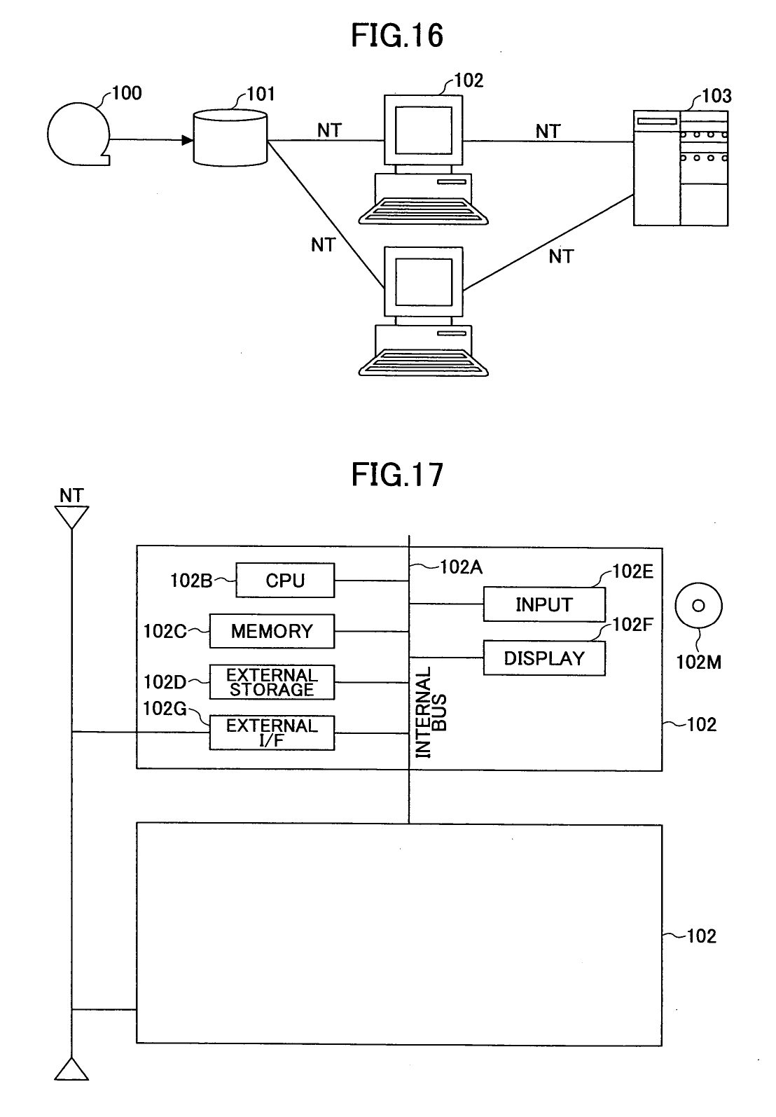

FIG. 16 shows the construction of a mask fabrication system executing the pattern data creation method explained with reference to FIGS. 4-14.

Referring to FIG. 16, the mask fabrication system includes: an internal or external storage device 101 holding design data 100 before and after the correction; one or more workstations 102 cooperating with the storage apparatus 101 via a network NT; and an exposure mask fabrication apparatus 103 cooperating with the work stations 102, wherein the designer of the semiconductor device manipulates the design data held in the storage device 101 from one of the workstations.

The design data 100 thus corrected is processed by the workstation 102 connected to the network and the pattern data creation processing and pattern data correction processing explained with reference to FIG. 4 are carried out.

FIG. 17 shows the construction of the workstation 102.

Referring to FIG. 17, the workstation 102 is a typical computer that includes an internal bus 102A, and a CPU 102B, a memory 102C, an external storage device 102D, an input device 102E and a display device 102F are connected to the internal bus 102A. Further, the workstation 102 is connected to the network NT via an external interface 102G.

Thereby, it should be noted that the processing of FIGS. 4-14 is executed according to a program held in the external storage device 102D, wherein such a program is recorded in a computer-readable recording medium 102M and is read to the external storage device 102D via the input device 102E under control of the CPU 102B.

Such a program is read out from the external storage device 102D upon activation of the workstation 102 under control of the CPU 102B and expanded in the memory 102C. With this, the CPU 102B executes the pattern data creation processing explained with reference to FIGS. 4-14 while referring to the memory 102C.

Further, while the present invention has been explained with reference to preferred embodiments, the present invention is by no means limited to such specific examples and various variations and modifications may be made without departing from the scope of the present invention.

What is claimed is:

1. A pattern data creation method for creating mask pattern data on an exposure mask, said exposure mask having a surface divided into plural unit regions, said mask pattern data comprising pattern data parts each defined for one of said plural unit regions, each of said pattern data parts comprising pattern information of a pattern included in said unit region and header information indicative of a location of said unit region on said surface of said exposure mask, said pattern data creation method comprising the steps of:
replacing, in a part of said plural unit regions, said pattern information in said mask pattern data part with new pattern information; and
reconstructing said header for said unit region in which said pattern information is replaced.

2. The pattern data creation method as claimed in claim 1, wherein said mask pattern data corresponds to design data of a semiconductor device described in terms of cells, and wherein said step of replacing said pattern information is conducted for said design data in terms of said cells.

3. The pattern data creation method as claimed in claim 1, wherein said step of replacing said pattern information further comprises the step of carrying out proximity effect correction at least in a region of said exposure mask in which said replacement of said pattern information is achieved.

4. The pattern data creation method as claimed in claim 1, wherein said step of replacing said pattern information further includes the step of forming dummy patterns at least in a region of said exposure mask where replacement of said pattern information is made, based on said new pattern information.

5. The pattern data creation method as claimed in claim 1, wherein said unit region is specified in terms of a segment and a stripe defined on said surface of said exposure mask.

6. The pattern data creation method as claimed in claim 1, wherein said step of replacing said pattern information and said step of reconstructing said header are executed by a computer.

7. A method of fabricating a semiconductor device, comprising the steps of:
forming a pattern on an exposure mask according to a pattern data creation process, said pattern data creation process creating mask pattern data on an exposure mask, said exposure mask having a surface divided into plural unit regions, said mask pattern data comprising pattern data parts each defined for one of said plural unit regions, each of said pattern data parts comprising pattern information of a pattern included in said unit region and header information indicative of a location of said unit region on said surface of said exposure mask, said pattern data creation method comprising the steps of: replacing, in a part of said plural unit regions, said pattern information in said mask pattern data part with new pattern information; and reconstructing said header for said unit region in which said pattern information is replaced; and
forming an exposure pattern corresponding to said pattern on a semiconductor substrate by using said exposure mask.

8. A computer-readable medium recorded with a pattern data creation program for creating mask pattern data on an exposure mask, said exposure mask having a surface divided into plural unit regions, said mask pattern data comprising pattern data parts each defined for one of said plural unit regions, each of said pattern data parts comprising pattern information of a pattern included in said unit region and header information indicative of a location of said unit region on said surface of said exposure mask, said pattern data creation program comprising:
program code means for replacing, in a part of said plural unit regions, said pattern information in said mask pattern data part with new pattern information; and
program code mans for reconstructing said header for said unit region in which said pattern information is replaced.

9. The computer-readable medium as claimed in claim 8, wherein said mask pattern data corresponds to design data of a semiconductor device described in terms of cells, and wherein said program code means for replacing said pattern information is conducted for said design data in terms of said cells.

10. The computer-readable medium as claimed in claim 8, wherein said program code means for replacing said pattern information further comprises program code means for carrying out proximity effect correction at least in a region of said exposure mask in which said replacement of said pattern information is achieved.

11. The computer-readable medium as claimed in claim 8, wherein said step of replacing said pattern information further includes the step of forming dummy patterns at least in a region of said exposure mask where replacement of said pattern information is made, based on said new pattern information.

12. The computer-readable medium as claimed in claim 8, wherein said unit region is specified in terms of a segment and a stripe defined on said surface of said exposure mask.

13. A computer specifically configured to execute a pattern data creation program for creating mask pattern data on an exposure mask, said exposure mask having a surface divided into plural unit regions, said mask pattern data comprising pattern data parts each defined for one of said plural unit regions, each of said pattern data parts comprising pattern information of a pattern included in said unit region and header information indicative of a location of said unit region on said surface of said exposure mask, said pattern data creation program comprising:
program code means for replacing, in a part of said plural unit regions, said pattern information in said mask pattern data part with new pattern information; and
program code mans for reconstructing said header for said unit region in which said pattern information is replaced.
